(19) United States
(12) Patent Application Publication
(10) Pub. No.: US 2026/0324044 A1
(43) Pub. Date: Oct. 15, 2026

(54) SEMICONDUCTOR DEVICE INCLUDING GATE DIELECTRIC WITH LOCALIZED DIPOLE ELEMENTS FOR THRESHOLD CONTROL

(71) Applicant: SAMSUNG ELECTRONICS CO., LTD., Suwon-si (KR)

(72) Inventors: Bumcheol KIM, Suwon-si (KR); Donghyun WANG, Suwon-si (KR); Myunggil KANG, Suwon-si (KR); Byounghak HONG, Suwon-si (KR)

(73) Assignee: SAMSUNG ELECTRONICS CO., LTD., Suwon-si (KR)

(21) Appl. No.: 19/564,943

(22) Filed: Mar. 12, 2026

(30) Foreign Application Priority Data
Apr. 15, 2025 (KR) 10-2025-0048723

(51) Int. Cl. H10D 64/68; H10D 30/00; H10D 30/01; H10D 62/00; H10D 62/13

(52) U.S. Cl. CPC H10D 64/685; H10D 30/019; H10D 30/501; H10D 62/021; H10D 62/151

(57) ABSTRACT

A semiconductor device includes a substrate having an active region, a gate structure intersecting the active region, a plurality of channel layers vertically spaced on the active region, and source/drain regions on opposite sides of the gate structure. The gate structure includes a gate electrode and a gate dielectric structure surrounding the channel layers. The gate dielectric structure includes an inner-side region disposed between the active region and a lowermost channel layer and between adjacent channel layers, and an outer-side region disposed on an uppermost channel layer. The inner-side region includes first portions adjacent to the source/drain regions and a second portion between the first portions, and a concentration of a dipole element in the first portions is greater than that in the second portion.

### CROSS-REFERENCE TO RELATED APPLICATION(S)

This application claims the benefit of priority to Korean Patent Application No. 10-2025-0048723 filed on Apr. 15, 2025 in the Korean Intellectual Property Office, the disclosure of which is incorporated herein by reference in its entirety.

### BACKGROUND

The present inventive concept relates to a semiconductor device. Specifically, the present inventive concept relates to a semiconductor device including a gate dielectric structure.

As the demand for high performance, high speed, and/or multifunctionality of semiconductor devices increases, a degree of integration of semiconductor devices is increasing. In manufacturing a semiconductor device with a fine pattern corresponding to the trend for a high degree of integration of semiconductor devices, it is necessary to implement patterns having a fine width or a fine separation distance. In addition, efforts are being made to develop a semiconductor device including a FinFET having a three-dimensional channel structure in order to overcome limitations of operating characteristics due to a decrease in size of a planar metal oxide semiconductor FET (MOSFET).

### SUMMARY

One of technical problems to be solved by the present inventive concept is to provide a semiconductor device having improved electrical characteristics by securing a gate electrode having a uniform threshold voltage.

However, purposes of the present inventive concept are not limited to the above-described purposes, and may be variously expanded without departing from the spirit and scope of the present inventive concept.

A semiconductor device according to embodiments includes a substrate including an active region extending in a first direction; a gate structure extending in a second direction, intersecting the active region, on the substrate; a plurality of channel layers spaced apart from each other in a third direction, perpendicular to an upper surface of the substrate, on the active region, and surrounded by the gate structure; and source/drain regions disposed on the active region on both sides of the gate structure and connected to the plurality of channel layers, wherein the gate structure includes a gate electrode; and a gate dielectric structure disposed between the active region and the gate electrode and surrounding the plurality of channel layers, wherein the gate dielectric structure includes an inner-side gate dielectric region disposed between the active region and a lowermost channel layer among the plurality of channel layers and between the plurality of channel layers, and including a first dipole element; and an outer-side gate dielectric region disposed on an uppermost channel layer among the plurality of channel layers, wherein the inner-side gate dielectric region includes first regions adjacent to the source/drain regions and spaced apart in the first direction, and a second region disposed between the first regions, and wherein a first concentration of the first dipole element in each of the first regions is greater than a second concentration of the first dipole element in the second region.

A semiconductor device according to embodiments includes a substrate including an active region extending in a first direction; a gate structure extending in a second direction, intersecting the active region, on the substrate; a plurality of channel layers spaced apart from each other in a third direction, perpendicular to an upper surface of the substrate, on the active region, and surrounded by the gate structure; and source/drain regions disposed on the active region on both sides of the gate structure and connected to the plurality of channel layers, wherein the gate structure includes an inner-side gate electrode disposed between the active region and a lowest channel layer, among the plurality of channel layers, and between the plurality of channel layers; an outer-side gate electrode extending from the inner-side gate electrode and disposed on an uppermost channel layer, among the plurality of channel layers; and a gate dielectric structure covering an upper surface of the active region and surrounding the plurality of channel layers, wherein the gate dielectric structure includes first regions adjacent to the source/drain regions and spaced apart in the first direction, and a second region between the first regions, wherein each of the first regions and the second region of the gate dielectric structures are in contact with the inner-side gate electrode and include a first dipole element, and wherein a first concentration of the first dipole element of each of the first regions is greater than a second concentration of the first dipole element of the second region.

A semiconductor device according to embodiments includes a substrate including an active region extending in a first direction; a gate structure extending in a second direction, intersecting the active region, on the substrate; a plurality of channel layers spaced apart from each other in a third direction, perpendicular to an upper surface of the substrate, on the active region, and surrounded by the gate structure; and source/drain regions disposed on the active region on both sides of the gate structure and connected to the plurality of channel layers, wherein the gate structure includes a gate electrode; and a gate dielectric structure disposed between the active region and the gate electrode and between the gate electrode and the plurality of channel layers, wherein the gate dielectric structure includes first regions adjacent to the source/drain regions between the plurality of channel layers and spaced apart in the first direction, and a second region disposed between the first regions, and wherein a first concentration of a first dipole element in each of the first regions is greater than a second concentration of the first dipole element in the second region.

A method for manufacturing a semiconductor device according to embodiments includes forming a stack structure including channel layers and sacrificial layers, alternately stacked on an active region extending in a first direction of a substrate; forming a sacrificial gate structure partially covering the stack structure and extending in a second direction, intersecting the first direction, and a gate spacer covering a sidewall of the sacrificial gate structure; etching the stack structure using the sacrificial gate structure and the gate spacer to form recess regions exposing sidewalls of the channel layers, sidewalls of the sacrificial layers, and an upper surface of the active region; forming source/drain regions in each of the recess regions; removing the sacrificial gate structure to form an upper gap region, and removing the sacrificial layers to form lower gap regions; forming a gate dielectric structure formed in the lower gap regions and surrounding the channel layers; forming dipole source patterns adjacent to the source/drain regions and spaced apart in the first direction on each of the gate dielectric structures; performing a drive-in annealing process on the dipole source patterns; and forming a gate electrode on the gate dielectric structure in the lower gap regions and the upper gap region.

According to an embodiment, the forming dipole source patterns may include forming a dipole source material layer on each of the gate dielectric structures in the lower gap regions; and removing a portion of the dipole source material layer to form the dipole source patterns.

According to an embodiment, the dipole source material layer may be removed through an isotropic etching process, and a length of the dipole source material layer in the first direction may be greater than a length in a third direction, intersecting the first direction and the second direction.

According to an embodiment, the dipole source material layer may include an air gap.

According to an embodiment, the method for manufacturing the semiconductor device may further include removing the dipole source patterns.

According to an embodiment, the forming a gate electrode may include forming an inner-side gate electrode in the lower gap regions; and forming an outer-side gate electrode in the upper gap region.

According to an embodiment, the method for manufacturing the semiconductor device may further include forming a gate dielectric liner covering an uppermost semiconductor layer among the channel layers and on a sidewall of the gate spacer, wherein the outer-side gate electrode may be formed on the gate dielectric liner.

According to an embodiment, the dipole source patterns may include lanthanum oxide (LaO).

According to an embodiment, the dipole source patterns may include at least one of aluminum oxide (Al₂O₃) or aluminum nitride (AlN).

According to an embodiment, the dipole source patterns may be spaced apart from each other in the first direction and a third direction, intersecting the first direction and the second direction.

### BRIEF DESCRIPTION OF DRAWINGS

The other aspects, features, and advantages of the present inventive concept will be more clearly understood from the following detailed description, taken in conjunction with the accompanying drawings, in which:

FIG. 1 is a plan view illustrating a semiconductor device according to embodiments.

FIG. 2 is a cross-sectional view illustrating an embodiment of the semiconductor device illustrated in FIG. 1, taken along lines I-I’ and II-II’.

FIG. 3 is an enlarged view of portion “A” according to an embodiment of the semiconductor device illustrated in FIG. 2.

FIG. 4A is an enlarged view of portion “B” according to an embodiment of the gate structure of the semiconductor device of FIG. 3.

FIGS. 4B-4D are enlarged views of portion “B” according to other embodiments of a gate structure of the semiconductor device of FIG. 3.

FIGS. 5 to 9, 10A, 10B, 11A, 11B, 12A, 12B, 13, 14A, 14B, 15A and 15B are views illustrating a process sequence illustrating a method for manufacturing a semiconductor device according to an embodiment.

### DETAILED DESCRIPTION

Hereinafter, with reference to the attached drawings, a preferred embodiment will be described in more detail. The same reference numerals may be used for the same components in the drawings, and duplicate descriptions of the same components will be omitted.

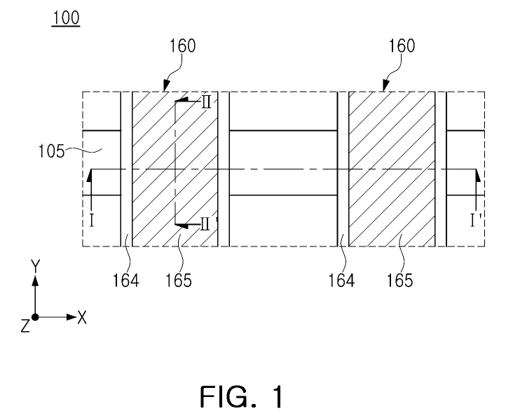

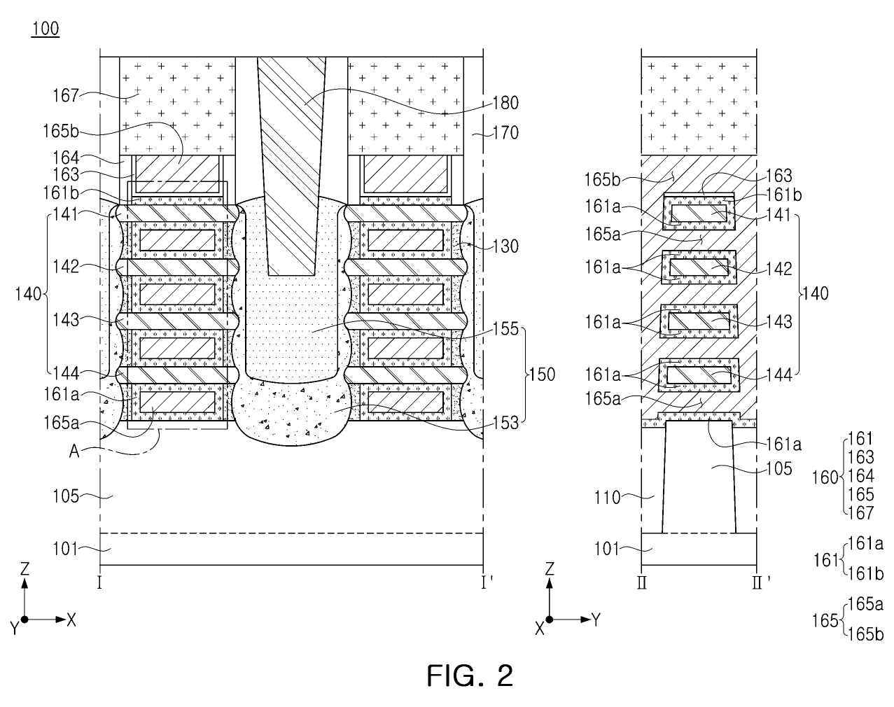

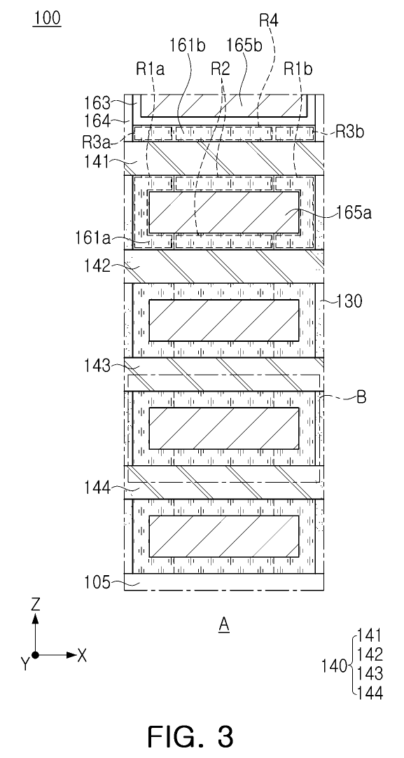

FIG. 1 is a plan view illustrating a semiconductor device according to embodiments. FIG. 2 is a cross-sectional view illustrating an embodiment of the semiconductor device illustrated in FIG. 1, taken along lines I-I’ and II-II’. FIG. 3 is an enlarged view of portion “A” according to an embodiment of the semiconductor device illustrated in FIG. 2.

Referring to FIGS. 1, 2 and 3, a semiconductor device 100 may include a substrate 101, an active region 105 on the substrate 101, device isolation layers 110 defining the active region 105, channel structures 140 each including a plurality of channel layers 141 to 144 disposed vertically and spaced apart from each other on the active region 105, a gate structure 160 extending to intersect the active region 105, source/drain regions 150 contacting the channel structures 140, internal spacers 130 disposed between the gate structure 160 and the source/drain regions 150, contact plugs 180 connected to the source/drain regions 150, and an interlayer insulating layer 170 surrounding the contact plugs 180 on the source/drain regions 150.

In the semiconductor device 100, the active region 105 may have a fin structure, and a gate electrode 165 may be disposed between the active region 105 and a channel structure 140, between the plurality of channel layers 141 to 144, and on the channel structure 140. Therefore, the semiconductor device 100 may include transistors having a multi bridge channel FET (MBCFET^{TM}) structure, which may be a gate-all-around type field effect transistor.

The substrate 101 may have an upper surface extending in a first direction (X-direction) and a second direction (Y-direction). The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOI) layer, or the like.

The substrate 101 may include active regions 105 disposed in an upper portion thereof. The active regions 105 may be defined by the device isolation layer 110 in the substrate 101, and may be disposed to extend in the first direction (X-direction). However, depending on a description method, it is also possible to describe the active regions 105 as a separate configuration from the substrate 101. The active regions 105 may partially protrude from the upper surface of the device isolation layer 110, such that an upper surface of the active regions 105 may be located on a higher level than an upper surface of the device isolation layer 110. The active regions 105 may be formed as a portion of the substrate 101 or may include an epitaxial layer grown from the substrate 101. On both sides of the gate structures 160, the active regions 105 may be partially recessed to form recess regions, and the source/drain regions 150 may be disposed in the recess regions.

The active region 105 may or may not include a well region containing impurities. For example, in an N-type transistor (nFET), the well region may include P-type impurities such as boron (B), gallium (Ga), or indium (In). In a P-type transistor (pFET), the well region may include N-type impurities such as phosphorus (P), arsenic (As), or antimony (Sb), and the well region may be located at a predetermined depth from the upper surface of the active region 105, for example.

The device isolation layer 110 may define the active region 105 in the substrate 101. The device isolation layer 110 may be formed, for example, by a shallow trench isolation (STI) process. The device isolation layer 110 may expose the upper surface of the active region 105, and may also expose a portion of an upper portion thereof. In some embodiments, the device isolation layer 110 may have a curved upper surface to have a higher level toward the active region 105. The device isolation layer 110 may be formed of an insulating material. The device isolation layer 110 may be, for example, an oxide, a nitride, or a combination thereof.

The gate structures 160 may be disposed on the active region 105 and the channel structures 140 to extend in the second direction (Y-direction) to intersect the active region 105 and the channel structures 140.

Each of the gate structures 160 may include a gate electrode 165, a gate dielectric structure 161 covering the upper surface of the substrate 101 and surrounding the plurality of channel layers 141 to 144, a gate dielectric liner 163 disposed on a lower surface and a sidewall of the gate electrode 165 disposed on the channel structure 140, gate spacer layers 164 on side surfaces of the gate dielectric liner 163, and a gate capping layer 167 disposed on the gate electrode 165.

The gate electrode 165 may be disposed to fill a space between the plurality of channel layers 141 to 144 on the active region 105 and extend onto the channel structure 140. The gate electrode 165 may include an inner-side gate electrode 165a filling a space between the active region 105 and a fourth channel layer 144, which may be the lowest channel layer among the plurality of channel layers 141 to 144, and between the plurality of channel layers 141 to 144, and an outer-side gate electrode 165b extending horizontally from the inner-side gate electrode 165a, and disposed on the channel structure 140. In a cross-section in the first direction (X-direction), a length of the inner-side gate electrode 165a in the first direction (X-direction) may be longer than a length of the inner-side gate electrode 165a in a vertical direction (Z-direction). In a cross-section in the second direction (Y-direction), the outer-side gate electrode 165b may include a first portion extending horizontally from the inner-side gate electrode 165a and overlapping the device isolation layer 110 in the vertical direction (Z-direction), and a second portion overlapping the channel structure 140 in the vertical direction (Z-direction) on the channel structure 140. In an example, the second portion of the outer-side gate electrode 165b may overlap the inner-side gate electrode 165a in the vertical direction (Z-direction).

The gate electrode 165 may include a conductive material, for example, a metal nitride such as a titanium nitride (TiN), a tantalum nitride (TaN), or a tungsten nitride (WN), and/or a metal material such as aluminum (Al), tungsten (W), molybdenum (Mo), or the like, or a semiconductor material such as doped polysilicon. According to embodiments, the gate electrode 165 may be formed as two or more multilayers.

The gate dielectric structure 161 may be disposed between the substrate 101 and the gate electrode 165 and between the plurality of channel layers 141 to 144 and the gate electrode 165. The gate dielectric structure 161 may be disposed to surround the plurality of channel layers 141 to 144 and all surfaces except for an uppermost surface of the gate electrode 165. In an example, the gate dielectric structure 161 may include an inner-side gate dielectric region 161a disposed between the active region 105 and the inner-side gate electrode 165a and between the plurality of channel layers 141 to 144 and the inner-side gate electrode 165a, and an outer-side gate dielectric region 161b extending to the inner-side gate dielectric region 161a. The inner-side gate dielectric region 161a may surround the inner-side gate electrode 165a below each of the plurality of channel layers 141 to 144, and may be in contact with the inner spacers 130. However, the present inventive concept is not limited thereto, and when the inner spacers 130 are omitted, the inner-side gate dielectric region may be in contact with the side surfaces of the source/drain regions 150. The outer-side gate dielectric region 161b may be disposed between the device isolation layer 110 and the first portion of the outer-side gate electrode 165b, between the side surfaces of the plurality of channel layers 141 to 144, and between a first channel layer 141, which may be an uppermost channel layer, and the second portion of the outer-side gate electrode 165b. The gate dielectric structure 161 may include an oxide, a nitride, or a high-κ material. The gate dielectric structure 161 may include a single dielectric layer, but is not limited thereto, and may include a plurality of dielectric layers. In an example, the inner-side gate dielectric region 161a of the gate dielectric structure 161 may be located between the inner-side gate electrode 165a and source/drain regions 150 to insulate the gate electrode 165 and the source/drain regions 150.

The gate electrode 165 may be separated from the plurality of channel layers 141 to 144 by the gate dielectric structure 161. The inner-side gate electrode 165a may be separated from the active region 105 and the plurality of channel layers 141 to 144 by the inner-side gate dielectric region 161a. The outer-side gate electrode 165b may be spaced from side surfaces of the plurality of channel layers 141 to 144 and the first channel layer 141, which may be an uppermost channel layer among the plurality of channel layers 141 to 144, by the outer-side gate dielectric region 161b.

The gate dielectric liner 163 may be disposed on a lower surface and both sidewalls of the gate electrode 165 disposed on the channel structure 140. In an example, the gate dielectric liner 163 may extend from between an upper surface of the outer-side gate dielectric region 161b disposed on an upper end of the first channel layer 141, which may be an uppermost channel layer, and the outer-side gate electrode 165b, to both sidewalls of the outer-side gate electrode 165b. For example, the gate dielectric liner 163 may extend from a lower surface of the outer-side gate electrode 165b to between the gate spacer layers 164 and the outer-side gate electrode 165b. The gate dielectric liner 163 may be formed integrally with the outer-side gate dielectric region 161b, but is not limited thereto. In an example, the gate dielectric liner 163 may include an oxide, a nitride, or a high-κ material. For example, the gate dielectric liner 163 may be any one of high-κ materials, such as aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

The gate spacer layers 164 may be spaced apart from each other in the first direction (X-direction) on the channel structure 140, and may be disposed on both side surfaces of the outer-side gate electrode 165b. The gate spacer layers 164 may be formed as a multilayer structure according to embodiments. The gate spacer layers 164 may be formed of at least one of an oxide, a nitride, or an oxynitride, and may be formed as, for example, a low-κ film.

The channel structures 140 may be disposed on the active region 105 in regions in which the active region 105 intersects the gate structures 160. The channel structure 140 may be surrounded by the gate structure 160, and may include the plurality of channel layers 141 to 144 disposed to be spaced apart from each other in the vertical direction (Z-direction). The plurality of channel layers 141 to 144 may include a first channel layer 141, a second channel layer 142, a third channel layer 143, and a fourth channel layer 144, spaced apart from each other in the vertical direction (Z-direction). The first channel layer 141 may be referred to as an uppermost channel layer among the plurality of channel layers 141 to 144, and may be referred to as an ‘uppermost channel layer 141’ in the present specification, and the fourth channel layer 144 may be referred to as a lowermost channel layer among the plurality of channel layers 141 to 144, and may be referred to as a ‘lowest channel layer 144’ in the present specification.

The channel structure 140 may be connected to the source/drain regions 150. A width of the channel structure 140 in the first direction (X-direction) may be greater than a width of the gate structure 160 in the first direction (X-direction). In an example, each of the plurality of channel layers 141 to 144 extending in the first direction (X-direction) may include a portion overlapping the gate electrode 165 in the vertical direction (Z-direction) and a remaining portion overlapping the internal spacers 130 and the gate dielectric structure 161 in the vertical direction (Z-direction).

In a cross-section in the second direction (Y-direction), among the first to fourth channel layers 141, 142, 143, and 144, a channel layer disposed in a lower portion may have a width, equal to or greater than a width of a channel layer disposed in an upper portion. The number and shapes of channel layers forming one channel structure 140 may be variously changed in embodiments. For example, one channel structure 140 may include three channel layers, may include two channel layers, or may include five or more channel layers.

The channel structures 140 may be formed of a semiconductor material, and may include, for example, at least one of silicon (Si), silicon germanium (SiGe), or germanium (Ge). The channel structures 140 may be formed of, for example, the same material as the active region 105. In some embodiments, the channel structures 140 may include an impurity region located adjacent to the source/drain regions 150.

The source/drain regions 150 may be in contact with the active region 105 on both sides of the gate structure 160. In an example, the source/drain regions 150 may be located in recess regions partially recessing an upper portion of the active region 105. The recess regions may extend along side surfaces of the channel structures 140 and side surfaces of the inner-side gate dielectric region 161a of the gate dielectric structure 161. The source/drain regions 150 may cover side surfaces of each of the first to fourth channel layers 141 to 144 of the channel structure 140 in the first direction (X-direction). Upper surfaces of the source/drain regions 150 may be located on the same level as or higher than a lower surface of the outer-side gate electrode 165b on the channel structure 140, and the level may be variously changed in embodiments. Side surfaces of the source/drain regions 150 may have a curvature according to the first to fourth channel layers 141 to 144 and the gate structure 160. Specific shapes of the side surfaces of the source/drain regions 150 may be variously changed in embodiments.

Each of the source/drain regions 150 may include a first epitaxial layer 153 and a second epitaxial layer 155 on the first epitaxial layer 153. In an example, the first epitaxial layer 153 may be disposed on the active region 105, and may extend to contact the plurality of channel layers 141 to 144. A surface in which the first epitaxial layer 153 is in contact with the plurality of channel layers 141, 142, and 143 and the internal spacers 130 may have a wavy shape, but is not limited thereto. A shape of the first epitaxial layer 153 may be changed depending on a shape of the channel structure 140, a shape of the gate structure 160, or the like. The first epitaxial layer 153 may have an approximately U-shape in a cross-section in the first direction (X-direction), but is not limited thereto. A lower end of the first epitaxial layer 153 may be disposed on a level, lower than a lower surface of the lower gate structure 160.

The second epitaxial layer 155 may be disposed on the first epitaxial layer 153. A lower surface of the second epitaxial layer 155 may have an approximately U-shaped round shape, but is not limited thereto. The first and second epitaxial layers 153 and 155 may include silicon germanium (SiGe) or silicon (Si) doped with a Group III element.

The first and second epitaxial layers 153 and 155 may have a P-type conductivity-type. For example, the first and second epitaxial layers 153 and 155 may include one of boron (B), aluminum (Al), gallium (Ga), indium (In), or thallium (Tl) as a doping element, while including silicon germanium (SiGe).

The first and second epitaxial layers 153 and 155 may have different germanium (Ge) concentrations. The first epitaxial layer 153 may include first silicon germanium (SiGe) including a first concentration of germanium (Ge), and the second epitaxial layer 155 may include second silicon germanium (SiGe) including a second concentration of germanium (Ge), higher than the first concentration.

The internal spacers 130 may be disposed between the gate structure 160 and the source/drain regions 150 below each of the plurality of channel layers 141 to 144 on the active region 105. The internal spacers 130 may cover side surfaces of the gate structure 160 in the first direction (X-direction) below each of the plurality of channel layers 141 to 144. The inner spacers 130 may be in contact with side surfaces of the inner-side gate dielectric region 161a of the gate dielectric structure 161 in the first direction (X-direction). The gate structure 160 below the uppermost channel layer 141 may be spaced apart from the source/drain regions 150 by the inner spacers 130. The inner spacers 130 may include an insulating material, and may include at least one of an oxide, a nitride, or an oxynitride. For example, the inner spacers 130 may include at least one of silicon oxide (SiO), silicon nitride (SiN), or silicon oxynitride (SiON). The inner-side gate electrode 165a may be stably spaced apart from the source/drain regions 150 by the inner spacers 130, and may be physically and electrically separated from the source/drain regions 150. In another embodiment, the inner spacers 130 may be omitted according to an embodiment, and the inner-side gate dielectric region 161a surrounding the inner-side gate electrode 165a may be in direct contact with the source/drain regions 150.

In an embodiment, a length in the first direction (X-direction) from the source/drain region 150 to the inner-side gate electrode 165a may be longer than a length in the vertical direction (Z-direction) from an upper surface of the inner-side gate electrode 165a to a lower surface of each of the plurality of channel layers 141 to 144. In an example, a length in the first direction (X-direction) from one surface of the inner spacer 130 in contact with the source/drain region 150 to one surface of the inner-side gate dielectric region 161a contacting a side surface of the inner-side gate electrode 165a may be longer than a width in the vertical direction (Z-direction) of the inner-side gate dielectric region 161a contacting the upper surface of the inner-side gate electrode 165a.

A functional channel region of a transistor may be formed in the active region 105 and/or the channel structures 140, intersecting the gate electrodes 165 of the gate structures 160.

The inner-side gate electrode 165a of the gate electrode 165 may fill a space between the active region 105 and the lowermost channel layer 144 and a space between the plurality of channel layers 141 to 144, between the source/drain regions 150. The inner-side gate electrode 165a may be disposed in relatively narrow regions compared to the outer-side gate electrode 165b.

Each of the plurality of channel layers 141 to 144 may include edge regions disposed at both ends in the first direction (X-direction), and the edge regions of each of the plurality of channel layers 141 to 144 may be spaced apart from the inner-side gate electrode 165a by the inner spacer 130 and the inner-side gate dielectric region 161a, and each of the plurality of channel layers 141 to 144 may include a center region between the edge regions of each of the plurality of channel layers 141 to 144, and the center region of each of the plurality of channel layers 141 to 144 may be spaced apart from the inner-side gate electrode 165a by the inner-side gate dielectric region 161a. In an example, a separation distance from the edge regions of each of the plurality of channel layers 141 to 144 to the inner-side gate electrode 165a may be greater than a separation distance from the center region of each of the plurality of channel layers 141 to 144 to the inner-side gate electrode 165a.

Referring to FIG. 3, the inner-side gate dielectric region 161a may surround the inner-side gate electrode 165a in each region between the active region 105 and the lowermost channel layer 144 and between the plurality of channel layers 141 to 144. The inner-side gate dielectric region 161a may include first regions R1a and R1b adjacent to the source/drain regions 150, and a second region R2 between the first regions R1a and R1b, in a cross-section in the first direction (X-direction). The first regions R1a and R1b and the second region R2 of the inner-side gate dielectric region 161a may include a first dipole element. A first concentration of the first dipole element in each of the first regions R1a and R1b may be greater than a second concentration of the first dipole element in the second region R2. The first concentration of the first dipole element in each of the first regions R1a and R1b may mean a maximum concentration or an average concentration of the first dipole element for each of the first regions R1a and R1b, and the second concentration of the first dipole element in the second region R2 may mean a maximum concentration or an average concentration of the first dipole element in the second region R2.

In an example, in an N-type transistor (nFET), the first dipole element may be, in an embodiment, materials shifting a threshold voltage (Vth) of the inner-side gate electrode 165a in a negative (-) direction. In an example, the first dipole element may include lanthanum (La). However, the present inventive concept is not limited thereto, and the first dipole element may include at least one rare earth element among gadolinium (Gd), lutetium (Lu), yttrium (Y), or scandium (Sc). As the first dipole element induces dipole formation in the inner-side gate dielectric region 161a to reduce a work function for edge regions of the inner-side gate electrode 165a, a threshold voltage for edge regions of the inner-side gate electrode 165a contacting the inner-side gate dielectric region 161a may be lowered.

In an example, in a P-type transistor (pFET), the first dipole element may be materials shifting a threshold voltage (Vth) of the inner-side gate electrode 165a in a positive (+) direction. For example, the first dipole element may include aluminum (Al). However, the present inventive concept is not limited thereto, and the first dipole element may include tantalum (Ta), tungsten (W), manganese (Mn), chromium (Cr), ruthenium (Ru), platinum (Pt), gallium (Ga), germanium (Ge), or gold (Au). As the first dipole element induces dipole formation in the inner-side gate dielectric region 161a to increase a work function for edge regions of the inner-side gate electrode 165a, a threshold voltage for edge regions of the inner-side gate electrode 165a contacting the inner-side gate dielectric region 161a may increase.

In an embodiment, each of the first regions R1a and R1b of the inner-side gate dielectric region 161a may include a higher dipole concentration than the second region R2, thereby securing a uniform threshold voltage value. For example, since each of the first regions R1a and R1b of the inner-side gate dielectric region 161a may include a higher dipole concentration than the second region R2, it is possible to compensate for a difference in threshold voltage between edge regions of the inner-side gate electrode 165a and a center region of the inner-side gate electrode 165a due to a difference in distance from the edge regions and the center region of each of the plurality of channel layers 141 to 144 to the inner-side gate electrode 165a.

In an embodiment, the outer-side gate dielectric region 161b may not include the first dipole element. For example, the gate dielectric structure 161 surrounding the uppermost channel layer 141 may include an inner-side gate dielectric region 161a disposed on a lower end of the uppermost channel layer 141, and an outer-side gate dielectric region 161b extending from the inner-side gate dielectric region 161a and disposed on an upper end of the uppermost channel layer 141, wherein the inner-side gate dielectric region 161a disposed on the lower end of the uppermost channel layer 141 may include the first dipole element, whereas the outer-side gate dielectric region 161b disposed on the upper end of the uppermost channel layer 141 may not include the first dipole element. The outer-side gate dielectric region 161b may include third regions R3a and R3b adjacent to the edge regions of the outer-side gate electrode 165b, and a fourth region R4 between the third regions R3a and R3b. The third regions R3a and R3b and the fourth region R4 may include an insulating material having the same composition. The third regions R3a and R3b of the outer-side gate dielectric region 161b may overlap the first regions R1a and R1b of the inner-side gate dielectric region 161a in the vertical direction (Z-direction), and the fourth region R4 of the outer-side gate dielectric region 161b may overlap the second region R2 of the inner-side gate dielectric region 161a in the vertical direction (Z-direction).

The inner-side gate dielectric region 161a may have a constant width. In an example, a width of the inner-side gate dielectric region 161a extending in the first direction (X-direction) between the plurality of channel layers 141 to 144 may be substantially equal to a width of the outer-side gate dielectric region 161b extending in the second direction (Y-direction). However, the present inventive concept is not limited thereto, and in another embodiment, the width of the inner-side gate dielectric region 161a extending in the first direction (X-direction) between the plurality of channel layers 141 to 144 may be greater than the width of the outer-side gate dielectric region 161b extending in the second direction (Y-direction).

A semiconductor device 100 according to an embodiment may include an inner-side gate electrode 165a filling a space between the active region 105 and the lowermost channel layer 144 and between the plurality of channel layers 141 to 144, and an inner-side gate dielectric region 161a surrounding the inner-side gate electrode 165a, wherein the inner-side gate dielectric region 161a may be adjacent to the source/drain regions 150, and first regions R1a and R1b contacting edge regions of the inner-side gate electrode 165a may have a relatively higher concentration of a dipole element than a second region R2 contacting a center region of the inner-side gate electrode 165a. Therefore, since it is possible to control to have a uniform threshold voltage value, a semiconductor device having improved electrical characteristics and reliability may be provided.

The interlayer insulating layer 170 may cover the source/drain regions 150, and the interlayer insulating layer 170 may include at least one of an oxide, a nitride, or an oxynitride, and may include, for example, a low-κ material. According to embodiments, the interlayer insulating layer 170 may include a plurality of insulating layers.

The contact plugs 180 may penetrate the interlayer insulating layer 170 to be connected to the source/drain regions 150, and may apply an electrical signal to the source/drain regions 150. The contact plugs 180 may recess the source/drain regions 150 from an upper surface, and may extend into the source/drain regions 150. The contact plugs 180 may include, for example, a metal nitride, such as titanium nitride (TiN), tantalum nitride (TaN), or tungsten nitride (WN), or may include a metal, such as titanium (Ti), cobalt (Co), molybdenum (Mo), or platinum (Pt). The contact plugs 180 may include a metal-semiconductor compound layer, such as a metal silicide layer, disposed on an interface contacting the source/drain regions 150.

The gate capping layer 167 may be disposed on the gate spacer layers 164 and the gate electrode 165. The gate capping layer 167 may be in contact with a side surface of the interlayer insulating layer 170 on the source/drain regions 150. The gate capping layer 167 may include at least one of an oxide, a nitride, or an oxynitride.

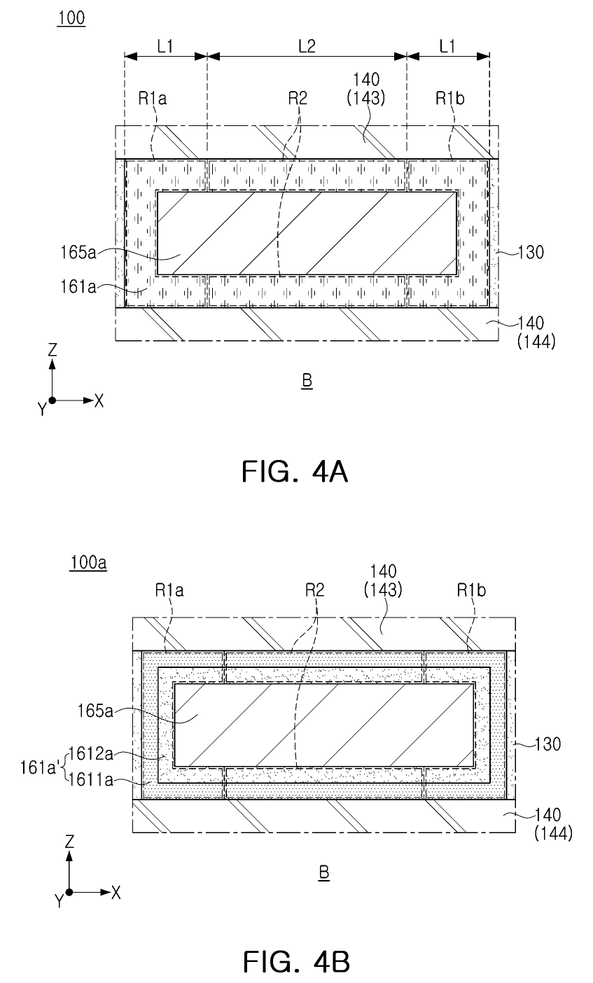

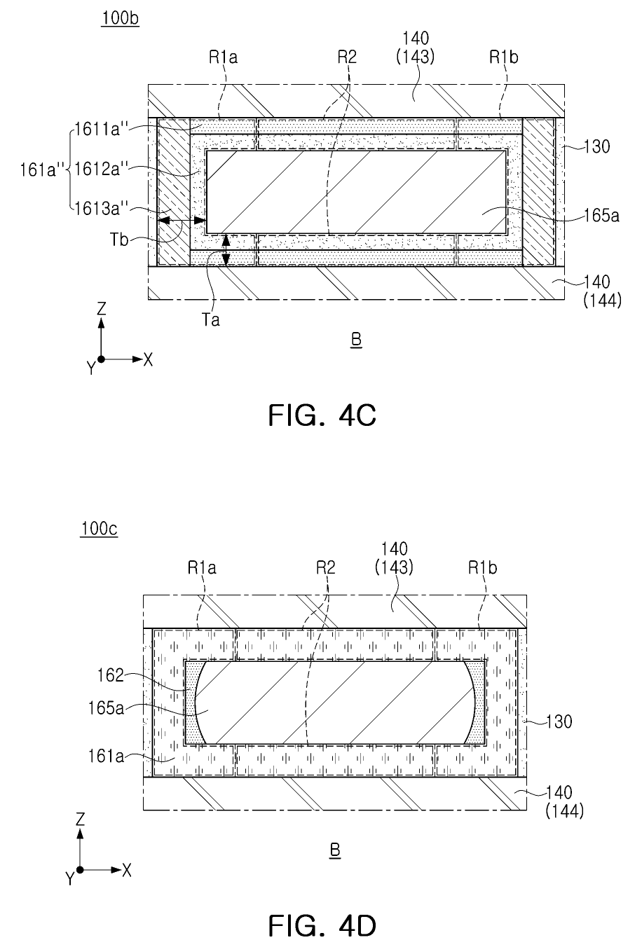

FIG. 4A is an enlarged view of portion “B” according to an embodiment of the gate structure of the semiconductor device of FIG. 3.

Referring to FIG. 4A, the inner-side gate dielectric region 161a may include first regions R1a and R1b and second regions R2, surrounding the inner-side gate electrode 165a and surrounding edge regions of the inner-side gate electrode 165a in a cross-section in the first direction (X-direction). The first regions R1a and R1b may be spaced apart in the first direction (X-direction), and may include a 1-1 region R1a having a ‘⊂’ shape, and a 1-2 region R1b opposing the 1-1 region R1a in the first direction (X-direction) and having a ‘⊃’ shape. Each of the first regions R1a and R1b may have a first length L1 in the first direction (X-direction) that contacts each of the plurality of channel layers 141 to 144, and the second region R2 may have a second length L2 in the first direction (X-direction) that contacts each of the plurality of channel layers 141 to 144. The first length L1 may be smaller than the second length L2.

Each of the first regions R1a and R1b of the inner-side gate dielectric region 161a may overlap the inner-side gate electrode 165a in a cross-section in the first direction (X-direction), and, in each of the first regions R1a and R1b, a length of a region overlapping the inner-side gate electrode 165a in the first direction (X-direction) may be about 0.1 times a length of the inner-side gate electrode 165a in the first direction (X-direction). For example, when the length of the inner-side gate electrode 165a in the first direction (X-direction) is about 10 nm, a length of each of the first regions R1a and R1b overlapping the inner-side gate electrode 165a in the first direction (X-direction) may be about 1 nm.

In an N-type transistor (nFET), the inner-side gate dielectric region 161a may include silicon oxide, silicon nitride, and/or a high-κ insulating material containing the first dipole element, lanthanum (La), as an impurity element. In a P-type transistor (pFET), the inner-side gate dielectric region 161a may include silicon oxide, silicon nitride, and/or a high-κ insulating material containing the first dipole element, aluminum (Al), as an impurity element.

Each of the first regions R1a and R1b of the inner-side gate dielectric region 161a may have a first concentration of the first dipole element, and the second region R2 of the inner-side gate dielectric region 161a may have a second concentration, lower than the first concentration of the first dipole element. In an example, the first concentration of the first dipole element in each of the first regions R1a and R1b may be about 1.2 times higher than the second concentration of the first dipole element in the second region R2. In an example, each of the first regions R1a and R1b may include about 0.6 at% (atomic %) to about 3 at% of the first dipole element (lanthanum (La) or aluminum (Al)), and the second region R2 may include about 0.5 at% to about 2.5 at% of the first dipole element. For example, when the first regions R1a and R1b and the second region R2 include lanthanum (La) as an impurity, each of the first regions R1a and R1b may include 1.8 at% (atomic %) lanthanum, and the second region R2 may include about 0 at% to about 1.5 at% lanthanum.

FIGS. 4B-4D are enlarged views of portion “B” according to other embodiments of a gate structure of the semiconductor device of FIG. 3.

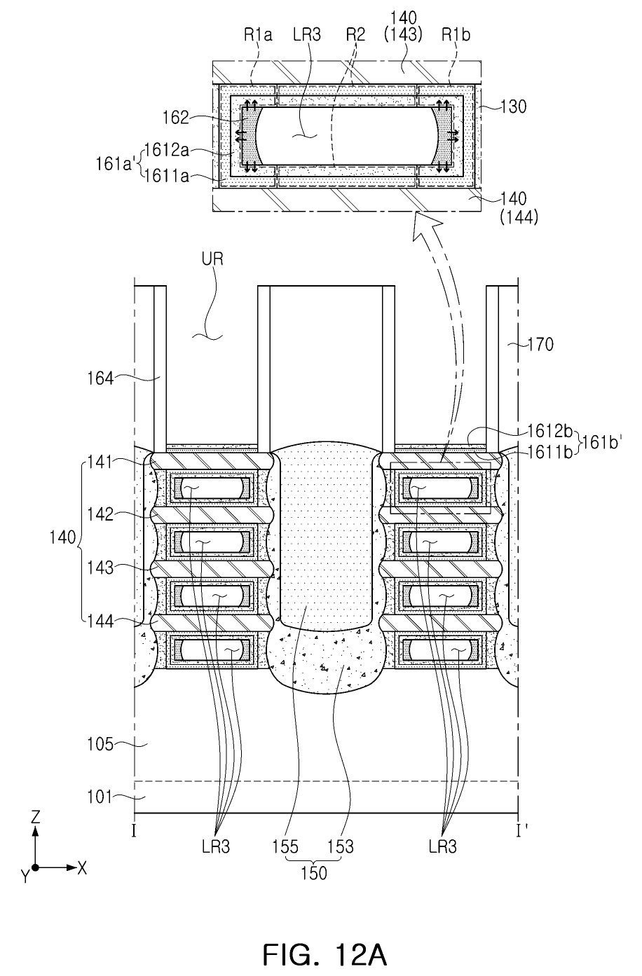

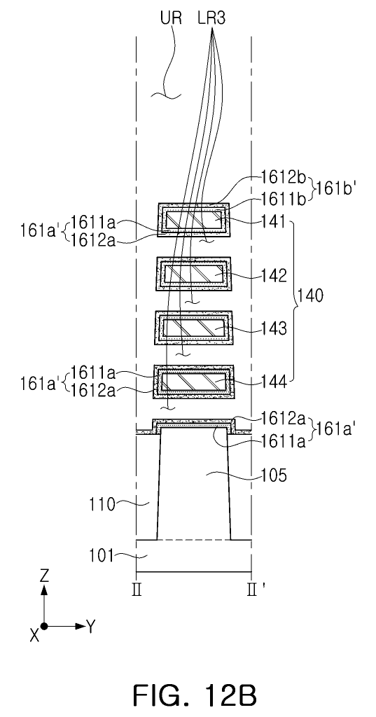

Referring to FIG. 4B, a semiconductor device 100a may include an inner-side gate dielectric region 161a’ and an outer gate dielectric structure (e.g., an outer-side gate dielectric region 161b’ of FIG. 12A), surrounding an inner-side gate electrode 165a. In an example, the inner-side gate dielectric region 161a’ may include a first gate dielectric layer 1611a contacting inner spacers 130 and a channel structure 140, and a second gate dielectric layer 1612a on the first gate dielectric layer 1611a. The first gate dielectric layer 1611a may include a first insulating material, and the second gate dielectric layer 1612a may include a second insulating material having a higher permittivity than the first insulating material. For example, the first gate dielectric layer 1611a may include silicon oxide and/or silicon nitride, and the second gate dielectric layer 1612a may include a second insulating material having a higher permittivity than the first insulating material. The second gate dielectric layer 1612a may include a dielectric material having a higher dielectric material than the silicon nitride. For example, the first gate dielectric layer 1611a may include silicon oxide (SiO₂), and the second gate dielectric layer 1612a may include hafnium oxide (HfO₂).

The inner-side gate dielectric region 161a’ may include silicon oxide (SiO₂) and hafnium oxide (HfO₂) including a first dipole element as an impurity. Each of the first regions R1a and R1b of the first gate dielectric layer 1611a and the second gate dielectric layer 1612a may have a higher concentration of the first dipole element than the second region R2 of the first gate dielectric layer 1611a and the second gate dielectric layer 1612a.

In an embodiment, first regions R1a and R1b of the first gate dielectric layer 1611a may surround first regions R1a and R1b of the second gate dielectric layer 1612a. A second region R2 of the first gate dielectric layer 1611a may be disposed between the first regions R1a and R1b of the first gate dielectric layer 1611a, and a second region R2 of the second gate dielectric layer 1612a may be disposed between the first regions R1a and R1b of the second gate dielectric layer 1612a.

Referring to FIG. 4C, a semiconductor device 100b may include an inner-side gate dielectric region 161a” and an outer-side gate dielectric region (e.g., an outer-side gate dielectric region 161b’ of FIG. 12A), surrounding an inner-side gate electrode 165a. The inner-side gate dielectric region 161a” may include gate spacer patterns 1613a” contacting inner spacers 130 and spaced apart in the first direction (X-direction) between source/drain regions (e.g., the source/drain regions 150 of FIG. 2), first gate dielectric layers 1611a” contacting the channel structure 140 between the gate spacer patterns 1613a”, and second gate dielectric layers 1612a” disposed on the first gate dielectric layers 1611a” between the gate spacer patterns 1613a”.

The gate spacer patterns 1613a” may be disposed between the source/drain regions 150, between an active region 105 and a lowermost channel layer 144 and between a plurality of channel layers 141 to 144. The gate spacer patterns 1613a” may be disposed in first regions R1a and R1b of the inner-side gate dielectric region 161a”. The first gate dielectric layers 1611a” and the second gate dielectric layers 1612a” may be arranged across the first regions R1a and R1b and a second region R2.

The first gate dielectric layers 1611a” may be spaced apart in the vertical direction (Z-direction) between the gate spacer patterns 1613a” with an inner-side gate electrode 165a interposed therebetween, and the second gate dielectric layer 1612a” may be conformally disposed in a region formed by the gate spacer patterns 1613a” and the first gate dielectric layers 1611a” between the first gate dielectric layers 1611a”. The second gate dielectric layer 1612a” may surround the inner-side gate electrode 165a. An outer-side surface of the second gate dielectric layer 1612a” may be in contact with the gate spacer patterns 1613a” and the first gate dielectric layers 1611a”, and an inner-side surface of the second gate dielectric layer 1612a” may be in contact with the inner-side gate electrode 165a.

In an embodiment, a first thickness Ta of the inner-side gate dielectric region 161a” in the third direction (Z-direction) may be greater than a second thickness Tb of the inner-side gate dielectric region 161a” in the first direction (X-direction). In an example, a width of each of the gate spacer patterns 1613a” in the first direction (X-direction) may be greater than a width of each of the first gate dielectric layers 1611a” in the second region R2 in the second direction (Y-direction) and a width of each of the second gate dielectric layers 1612a” in the second region R2 in the second direction (Y-direction).

In an embodiment, the first gate dielectric layer 1611a” may include a first insulating material, the second gate dielectric layer 1612a” may include a second insulating material having a higher permittivity than that of the first insulating material, and each of the gate spacer patterns 1613a” may include a third insulating material having a lower permittivity than that of the second insulating material and a higher permittivity than that of the first insulating material. For example, the first gate dielectric layer 1611a” may include silicon oxide (SiO₂), the second gate dielectric layer 1612a” may include hafnium oxide (HfO₂), and the gate spacer pattern 1613a” may include silicon nitride (SiN).

The first regions R1a and R1b of the inner-side gate dielectric region 161a” may include the gate spacer pattern 1613a” and the first and second gate dielectric layers 1611a” and 1612a”, including a first dipole element. For example, the first regions R1a and R1b of the inner-side gate dielectric region 161a” may include silicon oxide (SiO₂), hafnium oxide (HfO₂), and silicon nitride (SiN), including lanthanum (La) (or aluminum (Al)).

The second region R2 of the inner-side gate dielectric region 161a” may include the first and second gate dielectric layers 1611a” and 1612a”, including the first dipole element. For example, the second region R2 of the inner-side gate dielectric region 161a” may include silicon oxide (SiO₂) and hafnium oxide (HfO₂), including lanthanum (La) (or aluminum (Al). In an example, a first concentration of the first dipole element in each of the first regions R1a and R1b of the inner-side gate dielectric region 161a” may be greater than a second concentration of the first dipole element in the second region R2 of the inner-side gate dielectric region 161a”.

In an example, the outer-side gate dielectric region (e.g., the outer-side gate dielectric region 161b’ of FIG. 12A) may not include the first dipole element, and may include a first outer-side gate dielectric layer 1611b (see FIG. 12A) and a second outer-side gate dielectric layer 1612b (see FIG. 12B).

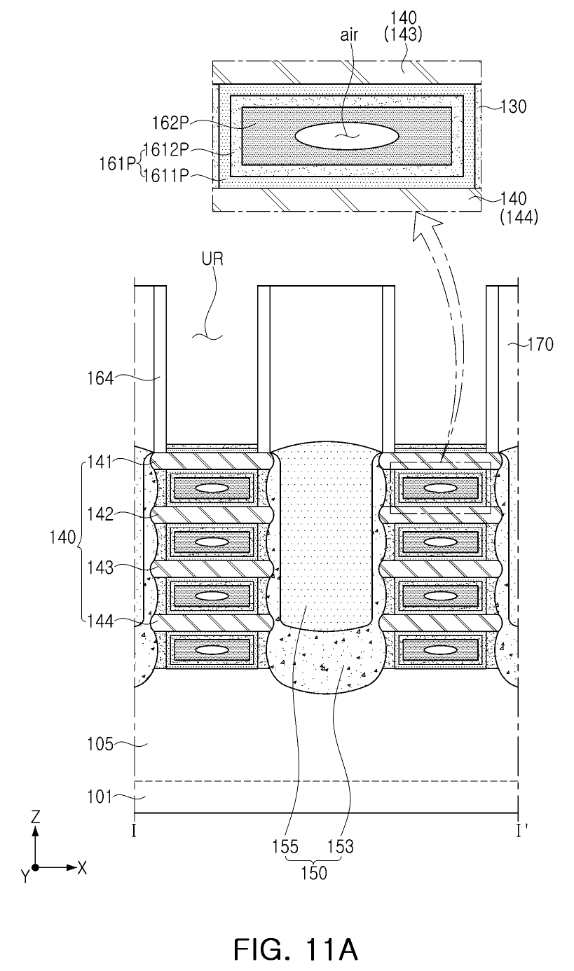

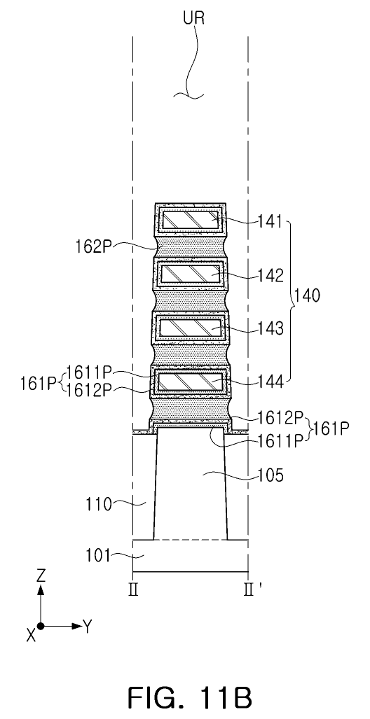

Referring to FIG. 4D, a semiconductor device 100c may include dipole source patterns 162 disposed between first regions R1a and R1b of an inner-side gate dielectric region 161a and an inner-side gate electrode 165a. The dipole source patterns 162 may be spaced apart in the first direction (X-direction), and may be disposed between a 1-1 region R1a of the inner-side gate dielectric region 161a and the inner-side gate electrode 165a, and between a 1-2 region R1b of the inner-side gate dielectric region 161a and the inner-side gate electrode 165a. The dipole source patterns 162 may include a first dipole element included in the inner-side gate dielectric region 161a. For example, in an N-type transistor (nFET), the dipole source pattern 162 may include lanthanum oxide (LaO). In a P-type transistor (pFET), the dipole source pattern 162 may include aluminum oxide (Al₂O₃) and/or aluminum nitride (AlN). In an embodiment, the dipole source patterns 162 may be a material remaining in removing a dipole source layer (e.g., a dipole source material layer 162P of FIG. 11A) during a process for manufacturing the semiconductor device 100c.

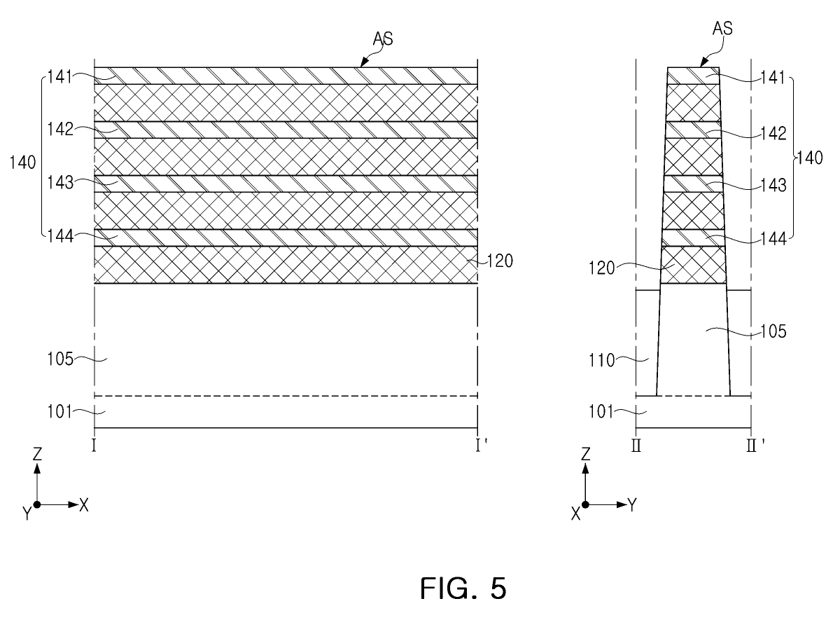

FIGS. 5 to 9, 10A, 10B, 11A, 11B, 12A, 12B, 13, 14A, 14B, 15A and 15B are views illustrating a process sequence illustrating a method for manufacturing a semiconductor device according to an embodiment. FIGS. 5 to 9, 10A, 10B, 11A, 11B, 12A, 12B, 13, 14A, 14B, 15A and 15B illustrate an embodiment of a method for manufacturing the semiconductor device of FIG. 4B.

Referring to FIG. 5, sacrificial layers 120 and first to fourth channel layers 141 to 144 may be alternately stacked on a substrate 101, and the first to fourth channel layers 141, 142, 143, and 144 and the substrate 101 may be partially removed to form an active structure AS including an active region 105, and a device isolation layer 110 may be formed.

The sacrificial layers 120 may be layers to be replaced with gate dielectric structures 161 and gate electrodes 165 below the first channel layer 141 through a subsequent process, as in FIG. 2. The sacrificial layers 120 may be formed of a material having etching selectivity with respect to the first to fourth channel layers 141, 142, 143, and 144. The first to fourth channel layers 141, 142, 143, and 144 may include a different material from the sacrificial layers 120. The sacrificial layers 120 and the first to fourth channel layers 141, 142, 143, and 144 may include a semiconductor material including at least one of, for example, silicon (Si), silicon germanium (SiGe), or germanium (Ge), but may include different materials, and may or may not include impurities. For example, the sacrificial layers 120 may include silicon germanium (SiGe), and the first to fourth channel layers 141, 142, 143, and 144 may include silicon (Si).

The sacrificial layers 120 and the first to fourth channel layers 141, 142, 143, and 144 may be formed by performing an epitaxial growth process from the stack structure. The number of layers of the channel layers alternately stacked with the sacrificial layers 120 may be variously changed in embodiments.

The active structure AS may include the active region 105, the sacrificial layers 120, and the first to fourth channel layers 141, 142, 143, and 144. The active structure AS may be formed in a linear shape extending in one direction, for example, the first direction (X-direction), and may be formed to be spaced apart from an adjacent active structure in the second direction (Y-direction). Side surfaces of the active structure AS in the second direction (Y-direction) may be coplanar with each other, and may be located on a straight line.

An insulating material may be filled in a region in which a portion of the active region 105, portions of the sacrificial layers 120, and portions of the first to fourth channel layers 141, 142, 143, and 144 are removed, and then the device isolation layer 110 may be formed by removing a portion of the insulating material such that the active region 105 protrudes. An upper surface of the device isolation layer 110 may be formed to be lower than an upper surface of the active region 105.

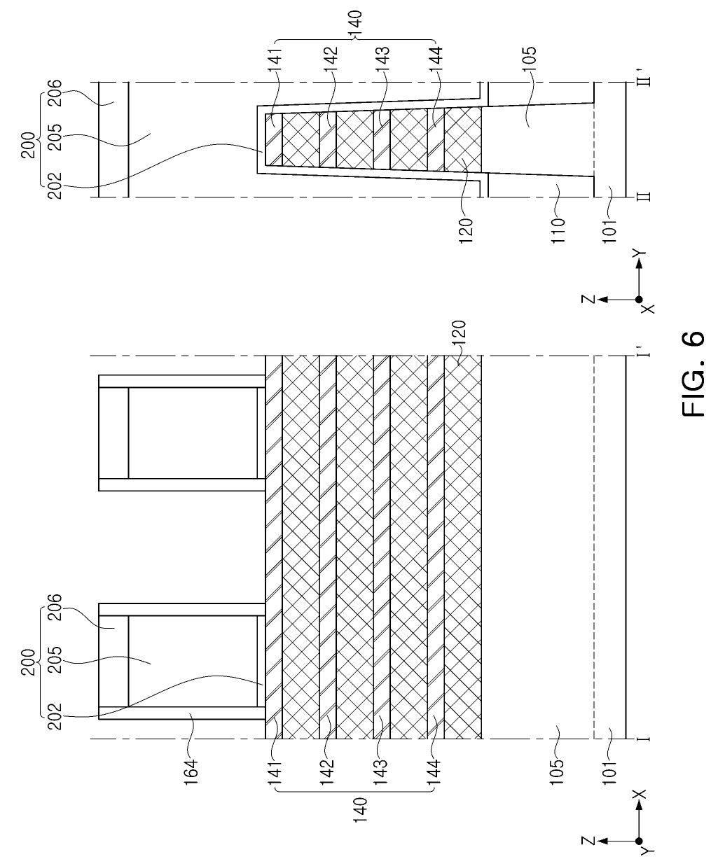

Referring to FIG. 6, sacrificial gate structures 200 and gate spacer layers 164 may be formed on the active structure AS.

Each of the sacrificial gate structures 200 may be a sacrificial structure formed in a region in which an outer-side gate dielectric region 161b, a gate dielectric liner 163, and an outer-side gate electrode 165b are disposed on the channel structure 140 through a subsequent process, as illustrated in FIG. 2. The sacrificial gate structures 200 may have a linear shape extending in one direction while intersecting the active structure. The sacrificial gate structures 200 may extend, for example, in the second direction (Y-direction). Each of the sacrificial gate structures 200 may include first and second sacrificial gate layers 202 and 205 and a mask pattern layer 206, sequentially stacked. The first and second sacrificial gate layers 202 and 205 may be patterned using the mask pattern layer 206.

The first and second sacrificial gate layers 202 and 205 may be an insulating layer and a conductive layer, respectively, but are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

The gate spacer layers 164 may be formed on both sidewalls of the sacrificial gate structures 200. The gate spacer layers 164 may be formed of a low-κ material, and may include at least one of SiO, SiN, SiCN, SiOC, SiON, or SiOCN, for example.

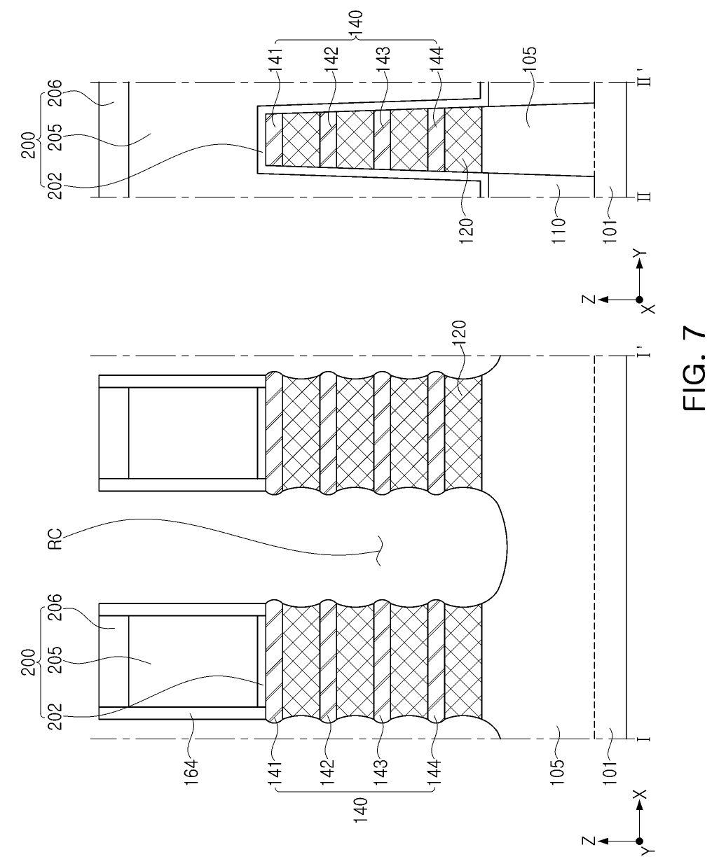

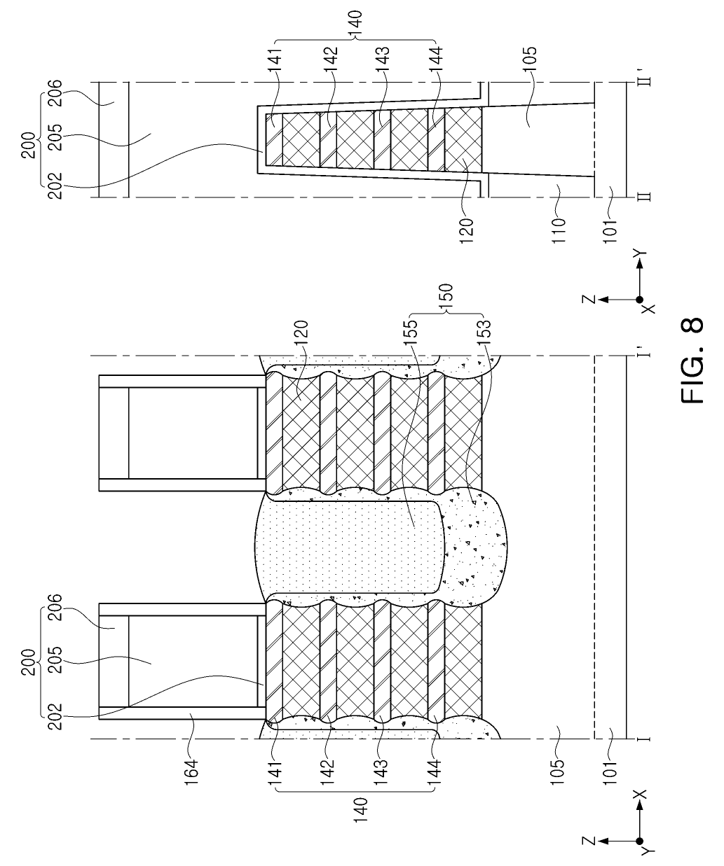

Referring to FIGS. 7 and 8, the active structure AS exposed from the sacrificial gate structures 200 may be partially removed to form recess regions RC, and source/drain regions 150 may be formed in the recess regions RC.

Using the sacrificial gate structures 200 and the gate spacer layers 164 as masks, portions of the exposed sacrificial layers 120 and portions of the first to fourth channel layers 141, 142, 143, and 144 may be removed to form the recess regions RC. As a result, the first to fourth channel layers 141, 142, 143, and 144 may form channel structures 140 having a limited length in the first direction (X-direction).

The source/drain regions 150 may be formed in the recess regions RC, and may be grown and formed from side surfaces of the active regions 105 and side surfaces of the channel structures 140, for example, by a selective epitaxial process. The source/drain regions 150 may include impurities by in-situ doping, and may include a plurality of layers having different doping elements and/or different doping concentrations. First epitaxial layers 153 may be formed by growing from upper surfaces of the active regions 105, side surfaces of the channel structures 140, and side surfaces of the sacrificial layers 120, for example, by a selective epitaxial process. Second epitaxial layers 155 may be formed by growing from the first epitaxial layers 153, for example, by a selective epitaxial process. The second epitaxial layers 155 may include impurities by in-situ doping.

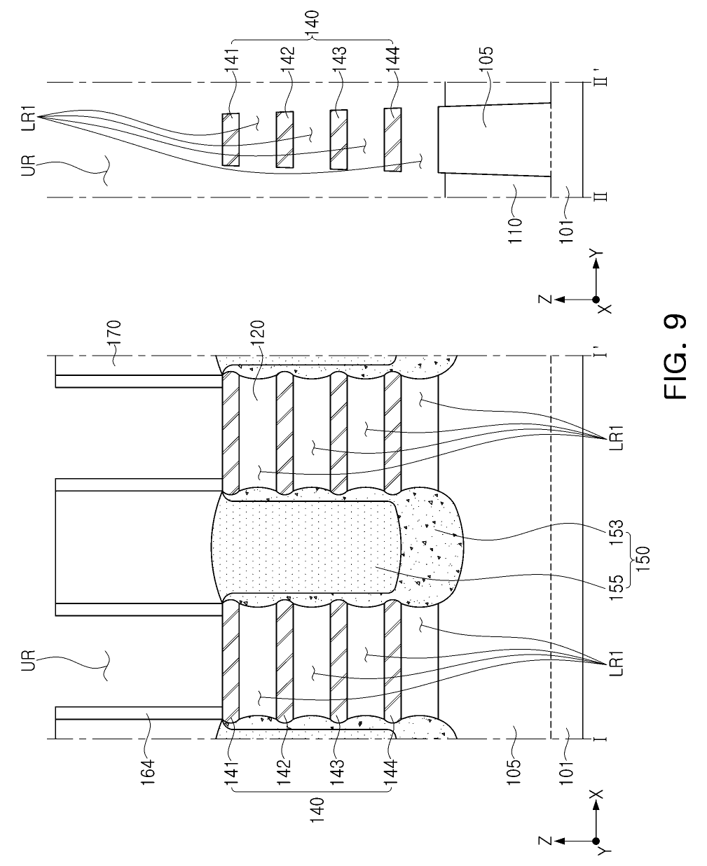

Referring to FIG. 9, an interlayer insulating layer 170 may be formed, and the sacrificial gate structures 200 and the sacrificial layers 120 may be removed.

The interlayer insulating layer 170 may be formed by forming an insulating film covering the sacrificial gate structures 200 and the source/drain regions 150, and performing a planarization process.

The sacrificial gate structures 200 and the sacrificial layers 120 may be selectively removed with respect to the gate spacer layers 164, and the channel structures 140. First, the sacrificial gate structures 200 may be removed to form upper gap regions UR, and then the sacrificial layers 120 exposed through the upper gap regions UR may be removed to form first lower gap regions LR1. For example, when the sacrificial layers 120 include silicon germanium (SiGe) and the channel structures 140 include silicon (Si), the sacrificial layers 120 may be selectively removed with respect to the channel structures 140 by performing a wet etching process.

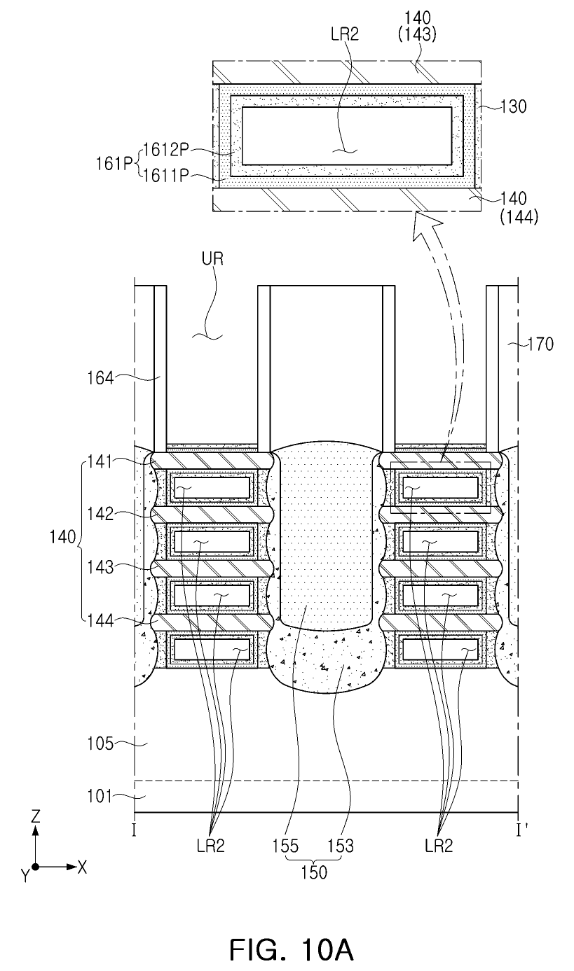

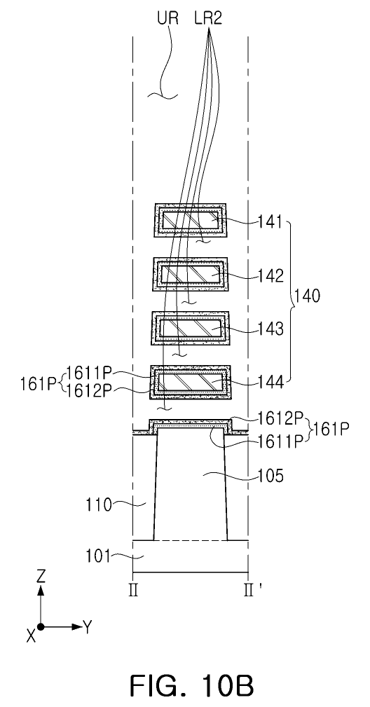

Referring to FIGS. 10A and 10B, internal spacers 130 may be formed, and a preliminary gate dielectric structure 161P surrounding the plurality of channel layers 141 to 144 may be formed in regions between the active region 105 and the fourth channel layer 144 and in regions between the plurality of channel layers 141 to 144.

The internal spacers 130 may be formed to cover side surfaces of the source/drain regions 150 in the first lower gap regions LR1. The internal spacers 130 may be formed by depositing and etching an insulating material in the first lower gap regions LR1.

The preliminary gate dielectric structure 161P may include a process of forming a first preliminary gate dielectric layer 1611P conformally formed in regions between the active region 105 and the fourth channel layer 144 and regions between the plurality of channel layers 141 to 144, and a process of forming a second preliminary gate dielectric layer 1612P on the first preliminary gate dielectric layer 1611P. In an embodiment, the first preliminary gate dielectric layer 1611P may be formed by performing an oxidation process on a surface of the active region 105 and surfaces of the plurality of channel layers 141 to 144. However, the present inventive concept is not limited thereto, and the first preliminary gate dielectric layer 1611P may be formed by an oxidation process and a deposition process. The second preliminary gate dielectric layer 1612P may be deposited on the first preliminary gate dielectric layer 1611P. The second preliminary gate dielectric layer 1612P formed on the first preliminary gate dielectric layer 1611P covering the active region 105 may be deposited to extend onto an upper surface of the device isolation layer 110. In an example, the first preliminary gate dielectric layer 1611P may include a first insulating material, and the second preliminary gate dielectric layer 1612P may include a second insulating material having a dielectric constant, higher than a dielectric constant of the first insulating material.

A surface of the preliminary gate dielectric structure 161P may be exposed through a second lower gap region LR2 between the active region 105 and the lowermost channel layer 144 and between the plurality of channel layers 141 to 144.

In the embodiment of FIG. 4C, an inner-side gate dielectric region 161a” may be manufactured by depositing and etching an insulating material on first lower gap regions LR1 between inner spacers 130, respectively, in this operation to form gate spacer patterns 1613a” spaced apart in the first direction (X-direction), performing an oxidation process on a surface of an active region 105 and surfaces of a plurality of channel layers 141 to 144 between the gate spacer patterns 1613a” to form first gate dielectric layers 1611a”, and forming a second gate dielectric layer 1612a” on the first gate dielectric layers 1611a” and the inner spacers 130 between the inner spacers 130.

Referring to FIGS. 11A and 11B, dipole source material layers 162P may be formed on the preliminary gate dielectric structure 161P in the second lower gap regions LR2. The dipole source material layers 162P may fill the second lower gap regions LR2 below each of the plurality of channel layers 141 to 144. The dipole source material layers 162P may be formed by an atomic layer deposition (ALD) process, a chemical vapor deposition (CVD) process, or a physical vapor deposition (PVD) process. At least a portion of the dipole source material layers 162P may include an air gap. In an N-type transistor (nFET), a dipole source material layer 162P may include lanthanum oxide (LaO). In a P-type transistor (pFET), the dipole source material layer 162P may include aluminum oxide (Al₂O₃) and/or aluminum nitride (AlN).

Referring to FIGS. 12A and 12B, a portion of the dipole source material layer 162P may be removed to form dipole source patterns 162 adjacent to the source/drain regions 150 and spaced apart in the first direction (X-direction), and a drive-in annealing process may be performed on the dipole source patterns 162.

The dipole source patterns 162 may be formed by performing an isotropic etching process through the air gap of the dipole source material layer 162P. In a cross-section in the first direction (X-direction), the dipole source patterns 162 spaced apart in the first direction (X-direction) may be formed as a result of performing an isotropic wet etching process on the dipole source material layer 162P according to an aspect ratio of each of a region between the active region 105 and a lowermost channel layer 144 and regions between the plurality of channel layers 141 to 144. In the cross-section in the first direction (X-direction), each of the region between the active region 105 and the lowermost channel layer 144 and the regions between the plurality of channel layers 141 to 144 may have a first length (horizontal length) in the first direction (X-direction) and a second length (vertical length) in the vertical direction (Z-direction), smaller than the first length.

Third lower gap regions LR3 exposing the dipole source patterns 162 and the preliminary gate dielectric structure 161P may be formed by an etching process for the dipole source material layer 162P.

A length of each of the dipole source patterns 162 in the first direction (X-direction) may be about 0.1 times a length of the preliminary gate dielectric structure 161P in the first direction (X-direction) in each of the third lower gap regions LR3. For example, a length of each of the dipole source patterns 162 in the first direction (X-direction) may be about 1 nm.

A drive-in annealing process may be performed on the dipole source patterns 162 such that a first dipole element corresponding to a composition constituting the dipole source patterns 162 may be diffused into the preliminary gate dielectric structure 161P. The drive-in annealing process may include a heat treatment process. For example, when the dipole source patterns 162 include lanthanum oxide (LaO), a first dipole element diffused into the preliminary gate dielectric structure 161P may be lanthanum (La), and when the dipole source patterns 162 include aluminum oxide (Al₂O₃) and/or aluminum nitride (AlN), a first dipole element diffused into the preliminary gate dielectric structure 161P may be aluminum (Al).

By the drive-in annealing process on the dipole source patterns 162, the first dipole element may be diffused into an inner-side gate dielectric region 161a’ disposed below the plurality of channel layers 141 to 144 of the preliminary gate dielectric structure 161P. The inner-side gate dielectric region 161a’ may include first regions R1a and R1b in which the dipole source patterns 162 are disposed and spaced apart in the first direction (X-direction), and a second region R2 between the first regions R1a and R1b. Since the first regions R1a and R1b may be disposed adjacent to the dipole source patterns 162, an amount of the first dipole element diffused into the first regions R1a and R1b may be greater than an amount of the first dipole element diffused into the second region R2, and therefore, a first concentration of the first dipole element in each of the first regions R1a and R1b may be higher than a second concentration of the first dipole element in the second region R2. For example, the first concentration of the first dipole element in each of the first regions R1a and R1b may be 1.2 times higher than the second concentration. In an embodiment, a first gate dielectric layer 1611a of the inner-side gate dielectric region 161a’ may include silicon oxide and/or silicon nitride, including lanthanum (La) (or aluminum (Al)) as an impurity, and a second gate dielectric layer 1612a of the inner-side gate dielectric region 161a’ may include hafnium oxide (HfO₂) including lanthanum (La) (or aluminum (Al)) as an impurity.

The first dipole element may not be diffused into an outer-side gate dielectric region 161b’ extending from the inner-side gate dielectric region 161a’ of the above-described preliminary gate dielectric structure 161P, and may be disposed on side surfaces of the plurality of channel layers 141 to 144 and an upper end of the uppermost channel layer 141, and a first outer-side gate dielectric layer 1611b and a second outer-side gate dielectric layer 1612b of the outer-side gate dielectric region 161b’ may include a dielectric material having the same composition. In an example, the first outer-side gate dielectric layer 1611b of the outer-side gate dielectric region 161b’ may include silicon oxide and/or silicon nitride, not including an impurity, and the second outer-side gate dielectric layer 1612b may include hafnium oxide (HfO₂) not including an impurity.

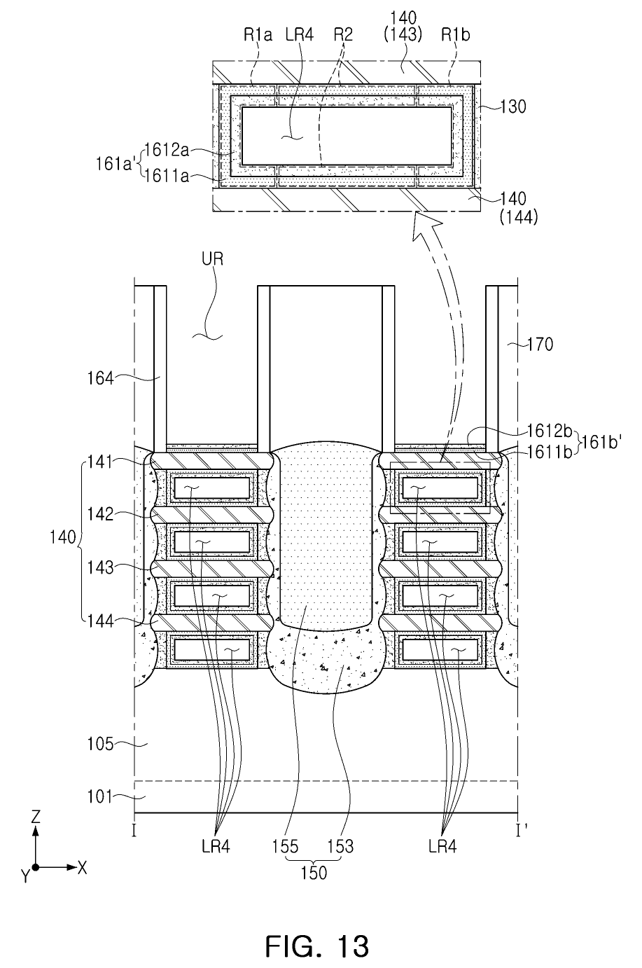

Referring to FIG. 13, the dipole source patterns 162 may be removed by a strip process. As the dipole source patterns 162 are removed, fourth lower gap regions LR4 in which the inner-side gate dielectric region 161a’ is exposed may be formed. In another embodiment, the dipole source patterns 162 may be removed through subsequent processes after a drive-in annealing process for the dipole source patterns 162.

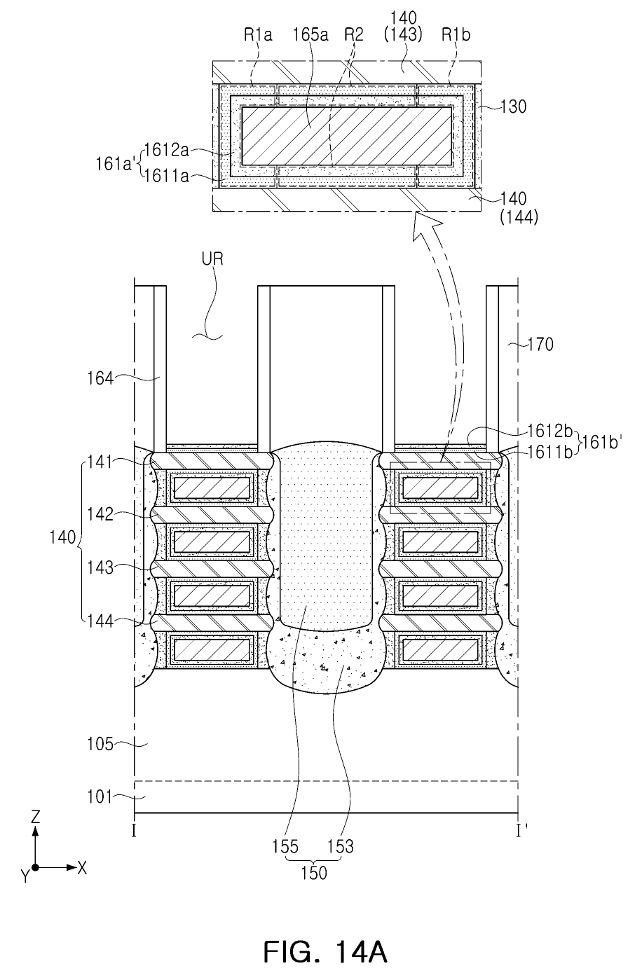

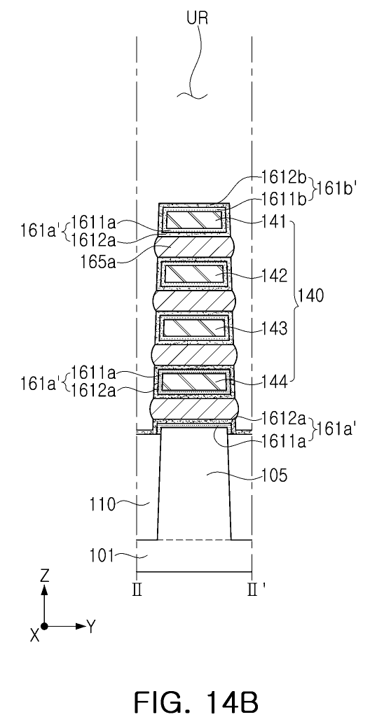

Referring to FIGS. 14A and 14B, an inner-side gate electrode 165a may be formed in the fourth lower gap regions LR4. The inner-side gate electrode 165a may be formed on the inner-side gate dielectric region 161a’ formed between the active region 105 and the lowermost channel layer 144 and between the plurality of channel layers 141 to 144. The inner-side gate electrode 165a may be formed by an atomic layer deposition (ALD) process, a chemical vapor deposition (CVD) process, or a physical vapor deposition (PVD) process.

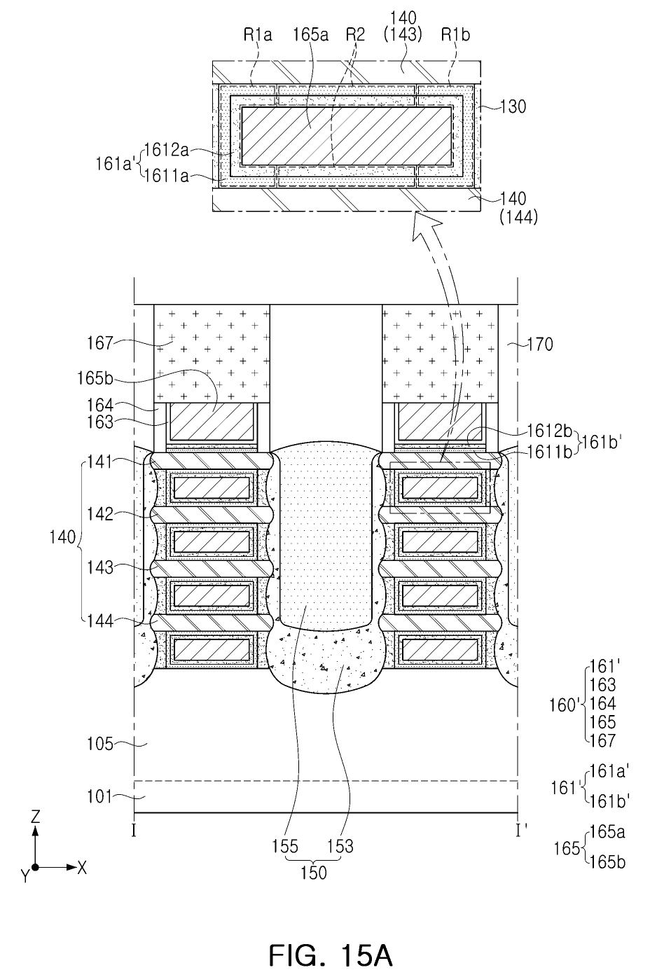

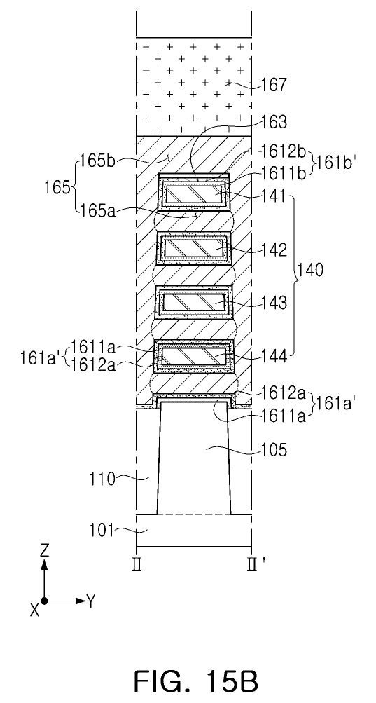

Referring to FIGS. 15A and 15B, a gate dielectric liner 163, an outer-side gate electrode 165b, and a gate capping layer 167 may be formed in the upper gap region UR. The gate dielectric liner 163 may be formed along an upper surface of the outer-side gate dielectric region 161b’ formed on the uppermost channel layer 141, and side surfaces of the gate spacer layers 164, in the upper gap region UR. The outer-side gate electrode 165b may be formed on the gate dielectric liner 163 extending from the inner-side gate electrode 165a. In an example, the outer-side gate electrode 165b may be formed by the same process as the inner-side gate electrode 165a, but is not limited thereto. In an example, in an N-type transistor (nFET), the inner-side gate electrode 165a and the outer-side gate electrode 165b may include different conductive materials. In a P-type transistor (pFET), the inner-side gate electrode 165a and the outer-side gate electrode 165b may include the same conductive material.

The gate capping layer 167 may be formed on the outer-side gate electrode 165b. As a result, a gate structure 160 including a gate dielectric structure 161, a gate electrode 165, the gate dielectric liner 163, gate spacer layers 164, and the gate capping layer 167 may be formed.

Thereafter, referring to FIG. 2, contact holes extending through the interlayer insulating layer 170 into the source/drain regions 150 may be formed, and then a space in the contact holes may be filled with a conductive material to form contact plugs 180.

A semiconductor device according to embodiments may include a gate dielectric structure surrounding a plurality of channel layers, and a concentration of a dipole element in edge regions adjacent to source/drain regions in the gate dielectric structure disposed between the plurality of channel layers may be formed to be higher than a concentration of the dipole element in a central region between the edge regions. Therefore, a threshold voltage of a gate electrode contacting the edge regions may be adjusted to secure a uniform threshold voltage of the gate electrode.

Effects of the present inventive concept are not limited to the above-described effects, and may be variously expanded in a range that does not depart from the spirit and scope of the present inventive concept.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate including an active region extending in a first direction;
a gate structure extending in a second direction, intersecting the active region, on the substrate;
a plurality of channel layers spaced apart from each other in a third direction, perpendicular to an upper surface of the substrate, on the active region, and surrounded by the gate structure; and
source/drain regions disposed on the active region on both sides of the gate structure and connected to the plurality of channel layers,
wherein the gate structure includes:
a gate electrode; and
a gate dielectric structure disposed between the active region and the gate electrode and surrounding the plurality of channel layers,
wherein the gate dielectric structure includes:
an inner-side gate dielectric region disposed between the active region and a lowermost channel layer among the plurality of channel layers and between the plurality of channel layers, and including a first dipole element; and
an outer-side gate dielectric region disposed on an uppermost channel layer among the plurality of channel layers,
wherein the inner-side gate dielectric region includes first regions adjacent to the source/drain regions and spaced apart in the first direction, and a second region disposed between the first regions, and
wherein a first concentration of the first dipole element in each of the first regions is greater than a second concentration of the first dipole element in the second region.

2. The semiconductor device of claim 1, wherein a length from each of the source/drain regions to the gate electrode in the first direction is longer than a length from a lower surface of each of the plurality of channel layers to an upper surface of the gate electrode in the third direction.

3. The semiconductor device of claim 1, wherein the outer-side gate dielectric region includes third regions adjacent to the source/drain regions, and a fourth region disposed between the third regions, and
the third regions and the fourth region include a dielectric material having the same composition.

4. The semiconductor device of claim 3, wherein the first regions overlap the third regions in the third direction, and
the second region overlaps the fourth region in the third direction.

5. The semiconductor device of claim 1, wherein the first concentration of the first dipole element in each of the first regions is about 1.2 times higher than the second concentration of the first dipole element in the second region.

6. The semiconductor device of claim 1, wherein the outer-side gate dielectric region is free of the first dipole element.

7. The semiconductor device of claim 1, wherein the gate dielectric structure includes a first gate dielectric layer contacting the active region and the plurality of channel layers, and a second gate dielectric layer disposed on the first gate dielectric layer,
the first gate dielectric layer includes a first insulating material, and
the second gate dielectric layer includes a second insulating material having permittivity, higher than permittivity of the first insulating material.

8. The semiconductor device of claim 1, wherein the inner-side gate dielectric region includes:
gate spacer patterns adjacent to the source/drain regions and spaced apart in the first direction, between the active region and the lowermost channel layer and between the plurality of channel layers;
a first gate dielectric layer contacting the active region and the plurality of channel layers, between the gate spacer patterns; and
a second gate dielectric layer disposed on the first gate dielectric layer between the gate spacer patterns.

9. The semiconductor device of claim 8, wherein the second gate dielectric layer is in contact with the gate spacer patterns exposed through between the active region and the lowermost channel layer and between the plurality of channel layers.

10. The semiconductor device of claim 8, wherein the first gate dielectric layer includes a first insulating material,
the second gate dielectric layer includes a second insulating material having permittivity, higher than permittivity of the first insulating material, and
the gate spacer patterns include a third insulating material having permittivity, higher than the permittivity of the first insulating material, and lower than the permittivity of the second insulating material.

11. The semiconductor device of claim 1, further including internal spacers disposed between the source/drain regions and the inner-side gate dielectric region.

12. The semiconductor device of claim 1, wherein the gate electrode includes an inner-side gate electrode surrounded by the inner-side gate dielectric region, and an outer-side gate electrode extended from the inner-side gate electrode and disposed on the outer-side gate dielectric region.

13. The semiconductor device of claim 12, further including dipole source patterns disposed between the first regions and the inner-side gate electrode and spaced apart in the first direction.

14. A semiconductor device comprising:
a substrate including an active region extending in a first direction;
a gate structure extending in a second direction, intersecting the active region, on the substrate;
a plurality of channel layers spaced apart from each other in a third direction, perpendicular to an upper surface of the substrate, on the active region, and surrounded by the gate structure; and
source/drain regions disposed on the active region on both sides of the gate structure and connected to the plurality of channel layers,
wherein the gate structure includes:
an inner-side gate electrode disposed between the active region and a lowest channel layer, among the plurality of channel layers, and between the plurality of channel layers;
an outer-side gate electrode extending from the inner-side gate electrode and disposed on an uppermost channel layer, among the plurality of channel layers; and
a gate dielectric structure covering an upper surface of the active region and surrounding the plurality of channel layers,
wherein the gate dielectric structure includes first regions adjacent to the source/drain regions and spaced apart in the first direction, and a second region between the first regions,
wherein each of the first regions and the second region of the gate dielectric structures are in contact with the inner-side gate electrode and include a first dipole element, and
wherein a first concentration of the first dipole element of each of the first regions is greater than a second concentration of the first dipole element of the second region.

15. The semiconductor device of claim 14, wherein a length of each of the first regions in the first direction is less than a length of the second region in the first direction.

16. The semiconductor device of claim 14, wherein the gate dielectric structure contacting the outer-side gate electrode is free of the first dipole element.

17. The semiconductor device of claim 14, wherein the first regions and the second region of the gate dielectric structure overlap the source/drain regions in the first direction.

18. The semiconductor device of claim 14, wherein the first dipole element includes lanthanum (La) or aluminum (Al).

19. The semiconductor device of claim 14, wherein the inner-side gate electrode includes a first conductive material, and
the outer-side gate electrode includes a second conductive material, that is different from the first conductive material.

20. A semiconductor device comprising:
a substrate including an active region extending in a first direction;
a gate structure extending in a second direction, intersecting the active region, on the substrate;
a plurality of channel layers spaced apart from each other in a third direction, perpendicular to an upper surface of the substrate, on the active region, and surrounded by the gate structure; and
source/drain regions disposed on the active region on both sides of the gate structure and connected to the plurality of channel layers,
wherein the gate structure includes:
a gate electrode; and
a gate dielectric structure disposed between the active region and the gate electrode and between the gate electrode and the plurality of channel layers,
wherein the gate dielectric structure includes first regions adjacent to the source/drain regions between the plurality of channel layers and spaced apart in the first direction, and a second region disposed between the first regions, and
wherein a first concentration of a first dipole element in each of the first regions is greater than a second concentration of the first dipole element in the second region.
